(19) United States
(12) Patent Application Publication
(10) Pub. No.: US 2025/0105082 A1
(43) Pub. Date: Mar. 27, 2025

(54) PACKAGING STRUCTURE AND METHOD FOR FORMING THE SAME

(71) Applicant: JCET Management Co., LTD., Shanghai (CN)

(72) Inventor: Xiao GU, Shanghai (CN)

(21) Appl. No.: 18/812,173

(22) Filed: Aug. 22, 2024

(30) Foreign Application Priority Data
Sep. 27, 2023 (CN) 202311270850.9

(51) Int. Cl. H01L 23/36; H01L 23/00; H01L 23/31; H01L 23/498; H01L 25/065; H10B 80/00

(52) U.S. Cl. CPC H01L 23/36; H01L 23/3121; H01L 23/49838; H01L 24/13; H01L 24/32; H01L 25/0655; H10B 80/00; H01L 23/3171; H01L 2224/13023; H01L 2224/32225; H01L 2924/351

(57) ABSTRACT

A packaging structure includes a substrate, a semiconductor temperature control device including opposed first and second surfaces, with first and second columnar electrodes protruding on the first surface, a semiconductor chip including opposed back and functional surfaces, with an external terminal being on the functional surface, a molding layer covering the semiconductor chip and semiconductor temperature control device and disposed on the upper surface of the substrate, and first and second external connection protrusions electrically connected to the first and second columnar electrodes, respectively, and a third external connection protrusion electrically connected to the external terminal. The second surface of the semiconductor temperature control device is mounted on an upper surface of the substrate. The back surface of the semiconductor chip is mounted on the first surface of the semiconductor temperature control device. The molding layer exposes top surfaces of the first and second columnar electrodes and external terminal.

### CROSS-REFERENCE TO RELATED APPLICATIONS

This application claims the benefit of priority to Chinese Application No. 202311270850.9, filed on Sep. 27, 2023, which is hereby incorporated by reference in its entirety.

### TECHNICAL FIELD

The present disclosure relates to the field of packaging, and in particular to a packaging structure and a method for forming the same.

### BACKGROUND

Nowadays, electronic devices are rapidly developing in the direction of high integration, high assembly density, and high operating speed. The integration, packaging, density, and operating clock frequency of the semiconductor chip, which is the core of electronic devices, continue to increase while the size continues to shrink. Therefore, the heat generation per unit area of the semiconductor chips is constantly increasing, and the situation is more serious, especially for high-power electronic devices.

### SUMMARY

Some embodiments of the present disclosure provide a method for forming a packaging structure. The method includes providing a substrate; providing a semiconductor temperature control device, the semiconductor temperature control device including opposed a first surface and a second surface, with a first columnar electrode and a second columnar electrode protruding on the first surface; mounting the second surface of the semiconductor temperature control device on an upper surface of the substrate; providing a semiconductor chip, the semiconductor chip including opposed a back surface and a functional surface, with an external terminal being on the functional surface; mounting the back surface of the semiconductor chip on the first surface of the semiconductor temperature control device; forming, on the upper surface of the substrate, a molding layer covering the semiconductor chip and the semiconductor temperature control device, the molding layer exposing top surfaces of the first columnar electrode, the second columnar electrode, and the external terminal; and forming, on the molding layer, a first external connection protrusion electrically connected to the first columnar electrode, a second external connection protrusion electrically connected to the second columnar electrode, and a third external connection protrusion electrically connected to the external terminal.

In some embodiments, the first external connection protrusion and the second external connection protrusion are configured to be electrically connected with positive and negative electrodes of a direct current (DC) power source, so that the semiconductor temperature control device operates to absorb heat generated by the semiconductor chip, and the semiconductor temperature control device forms a cold end and a hot end during operation, with the cold end being an end close to the first surface and the hot end being another end close to the second surface.

In some embodiments, the semiconductor temperature control device includes a plurality of N-type semiconductors and a plurality P-type semiconductors arranged in a staggered manner and connected in series, a top layer ceramic substrate disposed on top surface of the plurality of N-type semiconductors and the plurality of N-type P-type semiconductors, and a bottom layer ceramic substrate disposed on bottom surface of the plurality of N-type semiconductors and P-type semiconductors. In some embodiments, the first columnar electrode and the second columnar electrode protrude on a surface of the top layer ceramic substrate, and are electrically connected to one N-type semiconductor and one P-type semiconductor at both ends of the plurality of N-type semiconductors and the plurality of N-type P-type semiconductors connected in series.

In some embodiments, the back surface of the semiconductor chip is mounted to the surface of the top layer ceramic substrate of the semiconductor temperature control device by a thermal conductive adhesive.

In some embodiments, the semiconductor chip is mounted on the first surface of the semiconductor temperature control device between the first columnar electrode and the second columnar electrode, or mounted on the first surface of the semiconductor temperature control device on a side of the first columnar electrode and the second columnar electrode.

In some embodiments, after the back surface of the semiconductor chip is mounted on the first surface of the semiconductor temperature control device, the top surface of the external terminal on the functional surface of the semiconductor chip is flush with the top surfaces of the first columnar electrode and the second columnar electrode protruding from the first surface of the semiconductor temperature control device.

In some embodiments, the method further includes forming, on the molding layer, a first redistribution layer electrically connected to the first columnar electrode, a second redistribution layer electrically connected to the second columnar electrode, and a third redistribution layer electrically connected to the external terminal, the first external connection protrusion being disposed on the first redistribution layer and electrically connected to the first redistribution layer, the second external connection protrusion being disposed on the second redistribution layer and electrically connected to the second redistribution layer, the third external connection protrusion being disposed on the third redistribution layer and electrically connected to the third redistribution layer.

In some embodiments, the substrate includes a plurality of packaging areas arranged in an array and a sawing street area disposed between adjacent packaging areas. In some embodiments, the semiconductor temperature control device and semiconductor chip are mounted respectively on the upper surface of each packaging area. In some embodiments, the molding layer covers the upper surface of the sawing street area of the substrate. In some embodiments, after forming the first external connection protrusion, the second external connection protrusion, and the third external connection protrusion, the molding layer and the substrate are diced along the sawing street area to form a plurality of discrete packages.

Some embodiments of the present disclosure also provide a packaging structure, including a substrate; a semiconductor temperature control device, the semiconductor temperature control device including opposed a first surface and a second surface, with a first columnar electrode and a second columnar electrode protruding on the first surface, the second surface of the semiconductor temperature control device being mounted on an upper surface of the substrate; a semiconductor chip, the semiconductor chip including opposed a back surface and a functional surface, with an external terminal being on the functional surface, the back surface of the semiconductor chip being mounted on the first surface of the semiconductor temperature control device; a molding layer covering the semiconductor chip and the semiconductor temperature control device and disposed on the upper surface of the substrate, the molding layer exposing top surfaces of the first columnar electrode, the second columnar electrode, and the external terminal; and a first external connection protrusion on the molding layer and electrically connected to the first columnar electrode, a second external connection protrusion on the molding layer and electrically connected to the second columnar electrode, and a third external connection protrusion on the molding layer and electrically connected to the external terminal disposed.

In some embodiments, the first external connection protrusion and the second external connection protrusion are configured to be electrically connected with positive and negative electrodes of a DC power source, so that the semiconductor temperature control device operates to absorb heat generated by the semiconductor chip, and the semiconductor temperature control device forms a cold end and a hot end during operation, with the cold end being an end close to the first surface and the hot end being another end close to the second surface.

In some embodiments, the semiconductor temperature control device includes a plurality of N-type semiconductors and a plurality of P-type semiconductors arranged in a staggered manner and connected in series, a top layer ceramic substrate disposed on top surface of the plurality of N-type semiconductors and the plurality of P-type semiconductors, a bottom layer ceramic substrate disposed on bottom surface of the plurality of N-type semiconductors and P-type semiconductors. In some embodiments, the first columnar electrode and the second columnar electrode protrude on a surface of the top layer ceramic substrate, and are electrically connected to one N-type semiconductor and P-type semiconductor at both ends of the plurality of N-type semiconductors and the plurality of P-type semiconductors connected in series.

In some embodiments, the back surface of the semiconductor chip is mounted to the surface of the top layer ceramic substrate of the semiconductor temperature control device by a thermal conductive adhesive.

In some embodiments, the semiconductor chip is mounted on the first surface of the semiconductor temperature control device between the first columnar electrode and the second columnar electrode, or mounted on the first surface of the semiconductor temperature control device on a side of the first columnar electrode and the second columnar electrode.

In some embodiments, a top surface of the external terminal on the functional surface of the semiconductor chip is flush with the top surfaces of the first columnar electrode and the second columnar electrode protruding from the first surface of the semiconductor temperature control device.

In some embodiments, the packaging structure further includes a first redistribution layer on the molding layer and electrically connected to the first columnar electrode, a second redistribution layer on the molding layer and electrically connected to the second columnar electrode, and a third redistribution layer on the molding layer and electrically connected to the external terminal. In some embodiments, the first external connection protrusion is disposed on the first redistribution layer and electrically connected to the first redistribution layer, the second external connection protrusion is disposed on the second redistribution layer and electrically connected to the second redistribution layer, and the third external connection protrusion is disposed on the third redistribution layer and electrically connected to the third redistribution layer.

In some embodiments, the external terminal is a metal pillar protruding from the functional surface of the semiconductor chip or an external solder pad disposed on the functional surface of the semiconductor chip.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIGS. 1-7 illustrate structural schematic diagrams of the formation process of a packaging structure, according to some aspects of the present disclosure.

FIG. 8 is a flowchart of a method for forming the packaging structure, according to some aspects of the present disclosure.

The present disclosure will be described with reference to the accompanying drawings.

### DETAILED DESCRIPTION

The specific embodiments of the present disclosure are described in detail below in conjunction with the accompanying drawings. In detailing the embodiments of the present disclosure, the schematic diagrams will not be locally enlarged according to the general scale for the convenience of illustration, and the schematic diagrams are only examples, which should not limit the scope of protection of the present disclosure herein. In addition, the three-dimensional spatial dimensions of length, width, and depth should be included in the actual production.

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be disposed between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnects are formed) and one or more dielectric layers.

It should be noted that the terms “comprising,” “including,” and “having,” and their variations, referred to in the present disclosure are intended to cover non-exclusive inclusion. The terms “first,” “second,” etc. are used to distinguish between similar objects and need not be used to describe a specific order or sequence unless the context clearly indicates that the data used in this way can be interchanged in appropriate circumstances. In addition, the embodiments and the features in the embodiments in the present disclosure may be combined with each other without conflict. Furthermore, in the above explanation, descriptions of well-known components and techniques have been omitted to avoid unnecessarily confusing the concepts of the present disclosure. In the various embodiments below, each embodiment focuses on the differences from other embodiments, and the same/similar parts between various embodiments can be referenced to (or referred to) each other.

At present, there are various heat dissipation schemes for semiconductor chips, and one more common scheme is to use semiconductor temperature control devices (or thermos-electric cooler “TEC”) to dissipate heat from semiconductor chips. When the semiconductor temperature control device is used to dissipate heat from the semiconductor chip, the semiconductor temperature control device is usually mounted on the surface of the heat dissipation cover above the semiconductor chip, and a thermal interface material is required to be formed between the heat dissipation cover and the semiconductor chip as well as between the heat dissipation cover and the semiconductor temperature control device in order to conduct heat. Such a heat dissipation scheme results in an increased thickness of the packaging structure. When heat is conducted to the semiconductor temperature control device through the two layers of thermal interface material and the heat dissipation cover, the path of heat conduction is longer, and the heat dissipation efficiency is poorer. Also, since the semiconductor temperature control device is a separate structure, it is necessary to set up an additional interface for the semiconductor temperature control device to connect to an external power source, which is extremely inconvenient and inflexible.

The packaging structure and the method for forming the same are provided in some of the foregoing embodiments of the present disclosure, and the method for forming the packaging structure include providing a substrate; providing a semiconductor temperature control device, the semiconductor temperature control device including opposed a first surface and a second surface, with a first columnar electrode and a second columnar electrode protruding on the first surface; mounting the second surface of the semiconductor temperature control device on an upper surface of the substrate; providing a semiconductor chip, the semiconductor chip including opposed a back surface and a functional surface, with an external terminal being on the functional surface; mounting the back surface of the semiconductor chip on the first surface of the semiconductor temperature control device; forming a molding layer covering the semiconductor chip and the semiconductor temperature control device on the upper surface of the substrate, the molding layer exposing top surfaces of the first columnar electrode, the second columnar electrode and the external terminal; and forming, on the molding layer, a first external connection protrusion electrically connected to the first columnar electrode, a second external connection protrusion electrically connected to the second columnar electrode, and a third external connection protrusion electrically connected to the external terminal.

Since the first columnar electrode and the second columnar electrode of the semiconductor temperature control device protrude on the first surface, the semiconductor chip can be mounted on the first surface of the semiconductor temperature control device between or on one side of the first columnar electrode and the second columnar electrode. And since the thickness of the substrate can be thinner, no heat dissipation cover is provided between the semiconductor temperature control device and the semiconductor chip, and only one layer of a thermal interface material (thermal conductive adhesive) is required, thereby reducing the thickness of the formed packaging structure, and shortening the heat transfer distance between the semiconductor chip and the semiconductor temperature control device. Thus, the heat generated by the semiconductor chip can be quickly transferred to the semiconductor temperature control device for release, thereby improving the heat dissipation performance of the semiconductor chip. At the same time, by forming a molding layer covering the semiconductor chip and the semiconductor temperature control device on the upper surface of the substrate, the molding layer exposes the top surfaces of the first columnar electrode, the second columnar electrode, and the external terminal to facilitate the integrated production of the first external connection protrusion, the second external connection protrusion, and the third external connection protrusion, and by using the first external connection protrusion, the second external connection protrusion, the first columnar electrode, and the second columnar electrode as ports, the semiconductor temperature control device can be connected electrically to both the positive and negative electrodes of the DC power source. As a result, the semiconductor temperature control device does not need to have additional ports connected to the DC power source, improving convenience and flexibility.

Some embodiments of the present disclosure first provide a method for forming a packaging structure described in detail below in conjunction with the accompanying drawings.

Referring to FIGS. 1 and 8, a substrate 100 is provided at operation 802. A semiconductor temperature control device 200 is provided at operation 804, which includes opposed a first surface and a second surface, and has protruding first columnar electrode 201 and second columnar electrode 202 on the first surface. The second surface of the semiconductor temperature control device 200 is mounted on an upper surface of the substrate 100 at operation 806.

On one hand, the substrate 100 is used as a carrier for subsequent processes; on the other hand, the substrate 100 may also be used as a heat sink to release heat from the second surface of the semiconductor temperature control device 200.

The material of the substrate 100 is a metal with high thermal conductivity. In some embodiments, the material of the substrate 100 is one or more of copper, aluminum, tungsten, gold, nickel, steel, or stainless steel. In other embodiments, the material of the substrate 100 may also be graphene or silicon with high thermal conductivity.

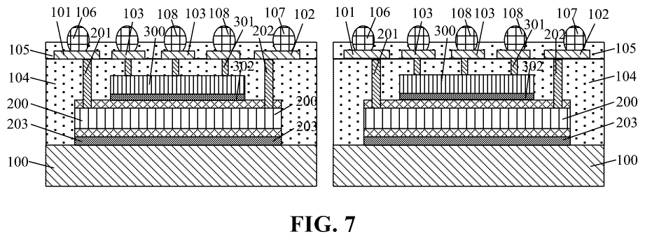

In some embodiments, the substrate 100 includes a plurality of packaging areas 11 arranged in an array and a sawing street area 12 disposed between adjacent packaging areas 11. The semiconductor temperature control device 200 and a semiconductor chip 300 are subsequently and respectively mounted on the upper surface of each packaging area 11 (referring to FIG. 6), and the sawing street area 12 is used to cut the formed packaging structure along the sawing street area 12 after subsequent formation of a first external connection protrusion, a second external connection protrusion, and a third external connection protrusion to form a number of discrete packages. In the present embodiment, two packaging areas 11 and a sawing street area 12 disposed between the two packaging areas 11 are illustrated as examples, and the specific number of the packaging areas 11 should not limit the protection scope of the present disclosure.

In some embodiments, the semiconductor temperature control device 200 serves as a thermos-electric cooler “TEC” for absorbing and releasing heat generated by the semiconductor chip 300 that is subsequently mounted (referring to FIG. 6). The semiconductor temperature control device 200 includes opposed a first surface and a second surface, and has protruding first columnar electrode 201 and a second columnar electrode 202 on the first surface. The first columnar electrode 201 and the second columnar electrode 202 are configured to be electrically connected to the positive and negative electrodes of a direct current (DC) power source by means of the subsequently formed first external connection protrusion and the second external connection protrusion, so that the semiconductor temperature control device 200 operates to absorb the heat generated by the semiconductor chip 300. The semiconductor temperature control device 200 forms a cold end and a hot end during operation. The cold end is the end close to the first surface, and the hot end is the end close to the second surface.

In some embodiments, the second surface of the semiconductor temperature control device 200 is mounted on the upper surface of the substrate 100 by a heat dissipating adhesive (thermal interface material) 203.

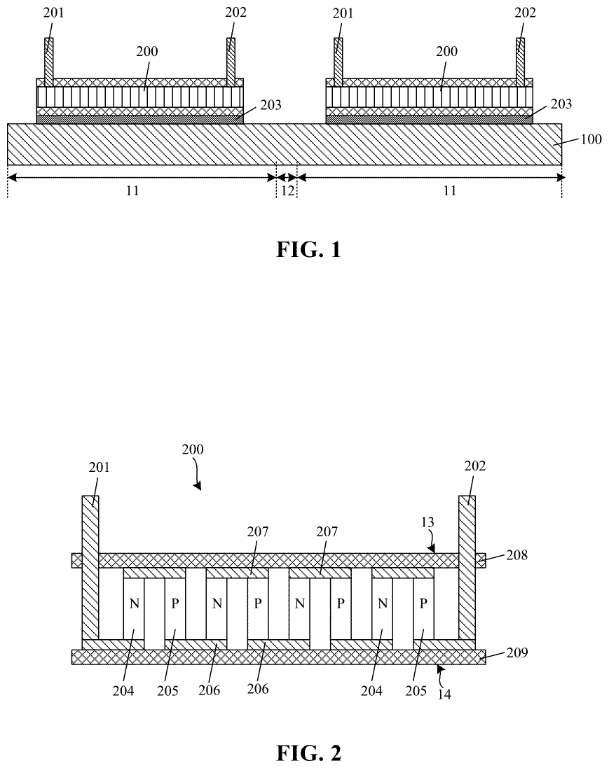

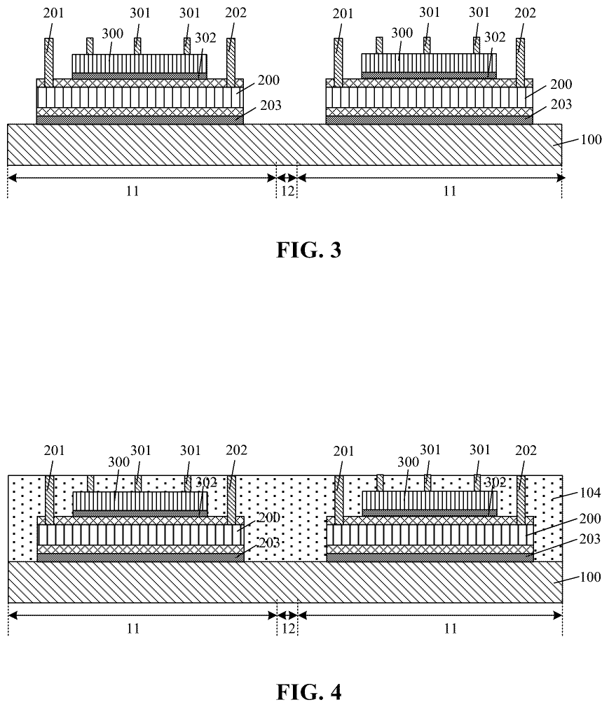

In some embodiments, referring to FIG. 2, the semiconductor temperature control device 200 includes a plurality of N-type semiconductors 204 and a plurality of P-type semiconductors 205 arranged in a staggered manner and connected in series. Specifically, the plurality of N-type semiconductors 204 and a plurality of P-type semiconductors 205 are arranged in a staggered manner, and the top ends of adjacent N-type semiconductors 204 and P-type semiconductors 205 are connected by a first metal layer 207, and the bottom ends of adjacent N-type semiconductors 204 and P-type semiconductors 205 are connected by a second metal layer 206 to form a series-connected structure. A top layer ceramic substrate 208 is disposed on the top surface of the plurality of N-type semiconductors 204 and P-type semiconductors 205 (on the upper surface of the first metal layer 207), and a bottom layer ceramic substrate 209 is disposed on the bottom surface of the plurality of N-type semiconductors 204 and P-type semiconductors 205 (on the lower surface of the second metal layer 206). The top layer ceramic substrate 208 and the bottom layer ceramic substrate 209 are used as an isolation layer and a heat-conducting layer, respectively. The surface where the top layer ceramic substrate 208 is disposed is used as the first surface of the semiconductor temperature control device 200, and the surface where the bottom layer ceramic substrate 209 is disposed is used as the second surface of the semiconductor temperature control device 200. The first columnar electrode 201 and the second columnar electrode 202 are electrically connected to one N-type semiconductor 204 and one P-type semiconductor 205 at both ends of the series-connected plurality of N-type semiconductors 204 and P-type semiconductors 205 (e.g., as shown in FIG. 2, the first columnar electrode 201 is electrically connected to the bottom of the N-type semiconductor 204 at one end (the leftmost end) of the series-connected plurality of N-type semiconductors 204 and P-type semiconductors 205, and the second columnar electrode 202 is electrically connected to the bottom of the P-type semiconductor 205 at the other end (the rightmost end) of the series-connected plurality of N-type semiconductors 204 and P-type semiconductors 205), and the first columnar electrode 201 and the second columnar electrode 202 are protruded on the surface of the top layer ceramic substrate 208, so that the semiconductor chip 300 may be subsequently mounted on the first surface of the semiconductor temperature control device 200 between or on one side of the first columnar electrode 201 and the second columnar electrode 202 (referring to FIG. 3). And since the thickness of the substrate 100 may be thinner, no heat dissipation cover is provided between the semiconductor temperature control device 200 and the semiconductor chip 300, and only one layer of a thermal interface material (thermal conductive adhesive) is required, thereby reducing the thickness of the subsequently formed packaging structure. The heat generated by the semiconductor chip 300 may be quickly transferred to the semiconductor temperature control device 200 for release, and the heat transfer distance from the semiconductor chip 300 to the semiconductor temperature control device 200 is shortened, so that the heat generated by the semiconductor chip 300 can be quickly transferred to the semiconductor temperature control device 200 for release, which improves the heat dissipation performance for the semiconductor chip 300. Meanwhile, a molding layer 104 covering the semiconductor chip 300 and the semiconductor temperature control device 200 is subsequently formed on the upper surface of the substrate 100 (referring to FIG. 6), and the molding layer 104 exposes the top surfaces of the first columnar electrode 201, the second columnar electrode 202, and subsequently formed external terminal 301 to facilitate the subsequent integrated production of the first external connection protrusion 106, the second external connection protrusion 107, and the third external connection protrusion 108 (referring to FIG. 6). By using the first external connection protrusion 106, the second external connection protrusion 107, the first columnar electrode 201, and the second columnar electrode 202 as ports, the semiconductor temperature control device 200 may be connected electrically to both the positive and negative electrodes of the DC power source, thereby it is unnecessary to provide additional ports for connecting to the DC power source in the semiconductor temperature control device 200, improving convenience and flexibility.

In some embodiments, when the semiconductor temperature control device 200 shown in FIG. 2 is used for heat dissipation of the semiconductor chip 300 in a subsequent packaging structure, the first columnar electrode 201 is connected to the positive electrode of the DC power source through the first external connection protrusion 106 formed subsequently, and the second columnar electrode 202 is connected to the negative electrode of the DC power source through the second external connection protrusion 107 formed subsequently, when the current flows from an N-type semiconductor 204 to an adjacent P-type semiconductor 205, the surface where the top layer ceramic substrate 208 is disposed (the end near the first surface of the semiconductor temperature control device 200) forms a cold end to absorb the heat generated by the semiconductor chip, and when the current flows from an P-type semiconductor 205 to an adjacent N-type semiconductor 204, the surface where the bottom layer ceramic substrate 209 is disposed (the end near the second surface of the semiconductor temperature control device 200) serves as a hot end to absorb heat from the cold end and release heat.

In other embodiments, the semiconductor temperature control device 200 shown in FIG. 2 may also be used for heating of semiconductor chips in subsequent packaging structure. Specifically, the first columnar electrode 201 is connected to the negative electrode of the DC power source through a first external connection protrusion 106 formed subsequently, the second columnar electrode 202 is connected to the positive electrode of the DC power source through a second external connection protrusion 107 formed subsequently, and the surface where the top layer ceramic substrate 208 is disposed (the end near the first surface of the semiconductor temperature control device 200) forms a hot end to release heat to heat the semiconductor chip, and the surface where the bottom layer ceramic substrate 209 is disposed (the end near the second surface of the semiconductor temperature control device 200) serves as a cold end to absorb heat from outside. The first columnar electrode 201 and the second columnar electrode 202 may be electrically connected to the positive or negative electrode of the DC power source through a corresponding control module.

In order to facilitate the subsequent mounting of the semiconductor chip 300 (referring to FIG. 3) on the first surface of the semiconductor temperature control device 200, the first columnar electrode 201 and the second columnar electrode 202 protrude on an edge area of the first surface of the semiconductor temperature control device 200 (the first surface of the semiconductor temperature control device 200 may include a mounting area and an edge area surrounding the mounting area, or the first surface of the semiconductor temperature control device 200 may also include a mounting area and an edge area disposed on one side of the mounting area, with the mounting area being subsequently mounted with a semiconductor chip). In some embodiments, when the first surface of the semiconductor temperature control device 200 includes a mounting area and an edge area surrounding the mounting area, the first columnar electrode 201 and the second columnar electrode 202 may be disposed on the same side or on different sides of the edge area (e.g., when the edge area is in the form of a quadrilateral ring, the edge area include four sides distributed along the four edges of the edge area, the first columnar electrode 201 and the second columnar electrode 202 may be disposed on different two sides of the four sides or on the same side of the four sides), and when subsequent mounting is carried out, the semiconductor chip 300 is mounted on the first surface of the semiconductor temperature control device 200 between or on one side of the first columnar electrode 201 and the second columnar electrode 202.

In some embodiments, the material of the first columnar electrode 201 and the second columnar electrode 202 is metal. For example, the material of the first columnar electrode 201 and the second columnar electrode 202 may be one or more of aluminum, nickel, tin, tungsten, platinum, copper, titanium, chromium, tantalum, gold, and silver.

Referring to FIGS. 3 and 8, a semiconductor chip 300 is provided at operation 808. The semiconductor chip 300 includes opposed a back surface and a functional surface, with external terminals 301 being on the functional surface. The back surface of the semiconductor chip 300 is mounted onto the first surface of the semiconductor temperature control device 200 at operation 810.

The semiconductor chip 300 releases heat outward during operation. The semiconductor chip 300 may include a logic chip or a memory chip. In some embodiments, the logic chip may include a gate array, a unit substrate array, an embedded array, a structured application-specific integrated circuit (ASIC), a field programmable gate array (FPGA), a complex programmable logic device (CPLD), a central processing unit (CPU), a microprocessor unit (MPU), a microcontroller unit (MCU), a logic integrated circuit (IC), an application processor (AP), a display driver IC (DDI), a radio frequency (RF) chip, a power source chip, or a complementary metal oxide semiconductor (CMOS) image sensor. In some embodiments, the memory chip may include a volatile memory chip (e.g., dynamic random-access memory (DRAM) or static RAM (SRAM)) or a non-volatile memory chip (e.g., flash memory (Flash), a phase-change RAM (PRAM), a magneto-resistive RAM (MRAM), a ferroelectric RAM (FeRAM), or a resistive RAM (ReRAM)). For example, the memory chip may include a high bandwidth memory (HBM) including a DRAM chip.

The semiconductor chip 300 includes opposed a back surface and a functional surface, with an external terminal 301 on the functional side on which the semiconductor chip 300 has a functional circuit. The external terminal 301 is electrically connected to the functional circuit. In the present embodiment, the external terminal 301 is a metal pillar protruding from the functional surface of the semiconductor chip 300. In other embodiments, the external terminals are external solder pads disposed on the functional surface of the semiconductor chip 300. In some embodiments, the material of the external solder pad is one or more of aluminum, nickel, tin, tungsten, platinum, copper, titanium, chromium, tantalum, gold, and silver, and the material of the metal pillar is one or more of aluminum, nickel, tin, tungsten, platinum, copper, titanium, chromium, tantalum, gold, and silver.

In some embodiments, the back surface of the semiconductor chip 300 is mounted on the first surface of the semiconductor temperature control device 200 by means of a thermally conductive adhesive (thermal interface material) 302. The thermally conductive adhesive 302 has both thermal conductivity and adhesion properties.

In some embodiments, after mounting the back surface of the semiconductor chip 300 on the first surface of the semiconductor temperature control device 200, the top surface of the external terminal 301 on the functional surface of the semiconductor chip 300 is flush with the top surfaces of the first columnar electrode 201 and the second columnar electrode 202 protruding from the first surface of the semiconductor temperature control device 200. When the molding layer 104 is subsequently formed (referring to FIG. 4), the top surfaces of the first columnar electrode 201, the second columnar electrode 202, and the external terminal 301 can be easily exposed by flattening the formed molding layer.

In some other embodiments, after mounting the back surface of the semiconductor chip 300 on the first surface of the semiconductor temperature control device 200, the top surface of the external terminal 301 on the functional surface of the semiconductor chip 300 is not flush with the top surfaces of the first columnar electrode 201 and the second columnar electrode 202 protruding from the first surface of the semiconductor temperature control device 200. After the molding layer is subsequently formed, it may be necessary to etch the molding layer to expose the top surface of the first columnar electrode 201, the second columnar electrode 202, and the external terminal 301.

In the present disclosure, the back surface of the semiconductor chip 300 is mounted on the first surface of the semiconductor temperature control device 200, thereby reducing the thickness of the packaging structure. The heat generated by the semiconductor chip 300 may be quickly conducted to the semiconductor temperature control device 200, absorbed and released by the semiconductor temperature control device 200, which improves the efficiency of heat dissipation of the semiconductor chip 300.

Referring to FIGS. 4 and 8, a molding layer 104 covering the semiconductor chip 300 and the semiconductor temperature control device 200 is formed on the upper surface of the substrate 100 at operation 812. The molding layer 104 exposes the top surfaces of the first columnar electrode 201, the second columnar electrode 202, and the external terminal 301. The molding layer 104 is used to seal and protect the semiconductor chip 300 and the semiconductor temperature control device 200.

In some embodiments, the material of the molding layer 104 is an epoxy resin, a polyimide resin, a benzocyclobutene resin, or a polybenzoxazole resin containing a filler. The material of the molding layer 104 may also be a polybutylene terephthalate, a polycarbonate, a polyglycol terephthalate, a polyethylene, a polypropylene, a polyolefin, a polyurethane, a polyolefin, a polyethersulfone, a polyamide, a polyimide, a vinyl-vinyl acetate copolymer, or polyvinyl alcohol containing a filler. The process for forming the molding layer 104 includes an injection molding process or a transfer molding process.

In some embodiments, the top surfaces of the first columnar electrode 201, the second columnar electrode 202, and the external terminal 301 may be exposed from the formed molding layer 104 through a chemical mechanical grinding process or etching process.

In some embodiments, when the substrate 100 includes a plurality of packaging area 11 arranged in an array and a sawing street area 12 disposed between adjacent packaging areas 11, the formed molding layer 104 also covers the upper surface of the sawing street area 12 of the substrate 100.

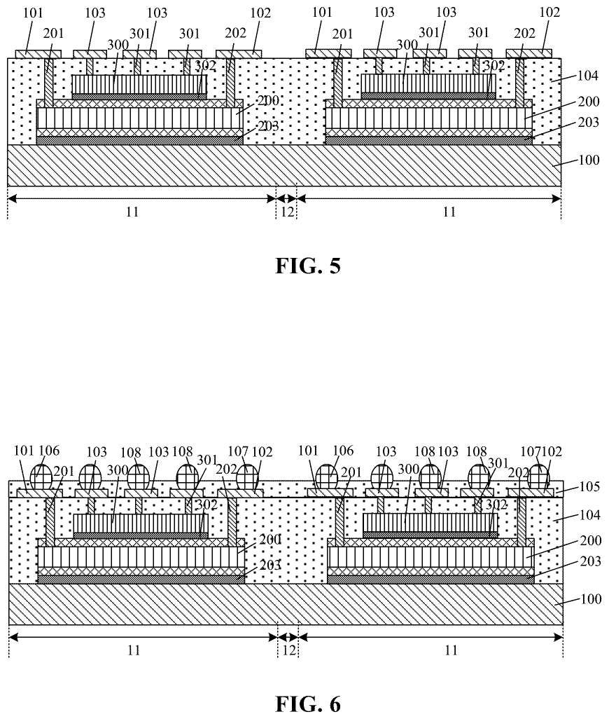

Referring to FIGS. 5, 6, and 8, a first external connection protrusion 106 electrically connected to the first columnar electrode 201, a second external connection protrusion 107 electrically connected to the second columnar electrode 202, and a third external connection protrusion 108 electrically connected to the external terminal 301 are formed on the molding layer 104 at operation 814.

The first external connection protrusion 106 and the second external connection protrusion 107 are used as ports for electrical connection with the positive and negative electrodes of the DC power source after the formation of the packaging structure, to connect with the positive and negative electrodes of the DC power source by means of the first external connection protrusion 106 and the second external connection protrusion 107. That is, the first columnar electrode 201 and the second columnar electrode 202 of the semiconductor temperature control device 200 may be electrically connected with the positive and negative electrodes of the DC power source, respectively, such that the semiconductor temperature control device 200 of the packaging structure can operate to absorb the heat generated by the semiconductor chip 300. The third external connection protrusion 108 is used as a port for connecting the semiconductor chip 300 of the packaging structure to other devices (such as other chips, substrates or packaging structures). That is, in the formation process of the packaging structure of the present disclosure, when the semiconductor temperature control device 200 and the semiconductor chip 300 are integrally packaged, the ports for connecting the semiconductor temperature control device 200 to the DC power source and the ports for connecting the semiconductor chip 300 to the other devices are integrally produced, so that there is no need to additionally provide the ports for connecting the semiconductor temperature control device 200 to the DC power source. At the same time, the packaging structure formed in the present disclosure has a thinner thickness, and the heat dissipation efficiency is improved.

In some embodiments, before forming the first external connection protrusion 106, the second external connection protrusion 107, and the third external connection protrusion 108, referring to FIG. 5, the method further includes forming a first redistribution layer 101 electrically connected to the first columnar electrode 201, a second redistribution layer 102 electrically connected to the second columnar electrode 202, and a third redistribution layer 103 electrically connected to the external terminal 301 on the molding layer 104. Referring to FIG. 6, a first external connection protrusion 106 disposed on the first redistribution layer 101 and electrically connected to the first redistribution layer 101 is formed, a second external connection protrusion 107 disposed on the second redistribution layer 102 and electrically connected to the second redistribution layer 102 is formed, and a third external connection protrusion 108 disposed on the third redistribution layer 103 and electrically connected to the third redistribution layer 103 is formed to increase the density of the wiring and optimize the layout. In other embodiments, the first redistribution layer 101, the second redistribution layer 102, and the third redistribution layer 103 may not be formed and thus, the first columnar electrode 201 is directly electrically connected to the first external connection protrusion 106, the second columnar electrode 202 is directly electrically connected to the second external connection protrusion 107, and the external terminal 301 is directly electrically connected to the third external connection protrusion 108.

In some embodiments, continuing to refer to FIG. 6, before forming the first external connection protrusion 106, the second external connection protrusion 107, and the third external connection protrusion 108, the method further includes forming a passivation layer 105 covering the first redistribution layer 101, the second redistribution layer 102, and the third redistribution layer 103 on the molding layer 104. The passivation layer 105 has a first opening exposing a portion of the surface of the first redistribution layer 101, a second opening exposing a portion of the surface of the second redistribution layer 102, and a third opening exposing a portion of the surface of the third redistribution layer 103. The method further includes forming a first external connection protrusion 106 electrically connected to the first redistribution layer 101 in the first opening, forming a second external connection protrusion 107 electrically connected to the second redistribution layer 102 in the second opening, and forming a third external connection protrusion 108 electrically connected to the third redistribution layer 103 in the third opening.

The material of the first redistribution layer 101, the second redistribution layer 102, and the third redistribution layer 103 is a metal, such as one or more of aluminum, nickel, tin, tungsten, platinum, copper, titanium, chromium, tantalum, gold, and silver.

The first external connection protrusion 106, the second external connection protrusion 107, and the third external connection protrusion 108 are in the form of a sphere or a trailing sphere. In some embodiments, the first external connection protrusion 106, the second external connection protrusion 107, and the third external connection protrusion 108 are one or more of tin, tin-silver, tin-lead, silver-copper, tin-silver-copper, tin-silver-zinc, tin-zinc, tin-bismuth-indium, tin-indium, tin-gold, tin-copper, tin-zinc-indium, or tin-silver-antimony.

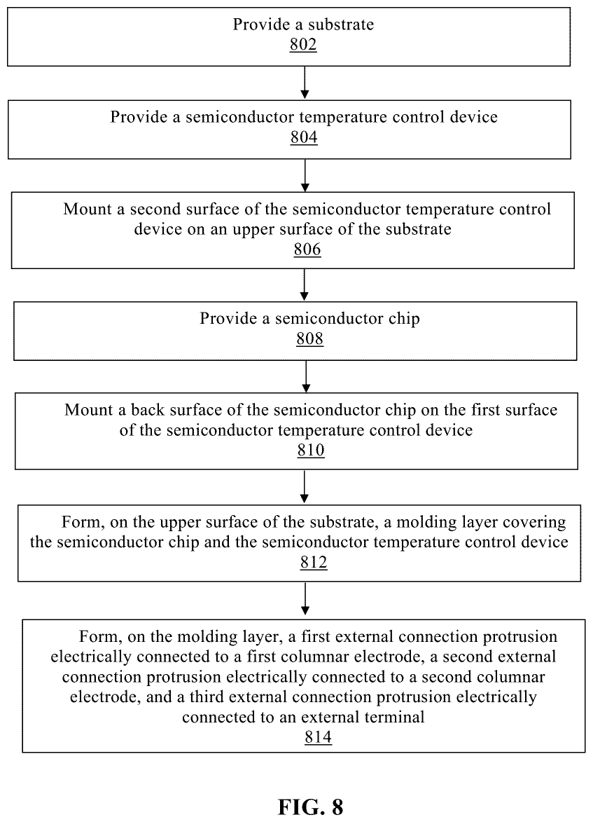

In some embodiments, referring to FIG. 7, after forming the first external connection protrusion 106, the second external connection protrusion 107, and the third external connection protrusion 108, the method further includes dicing the molding layer 104 and substrate 100 along the sawing street area 12 (referring to FIG. 6) to form a plurality of discrete packages.

Some embodiments of the present disclosure also provide a packaging structure, referring to FIG. 7, including, a substrate 100, a semiconductor temperature control device 200, a semiconductor chip 300, a molding layer 104, a first external connection protrusion 106, a second external connection protrusion 107, and a third external connection protrusion 108. The semiconductor temperature control device 200 includes opposed a first surface and a second surface, with a first columnar electrode 201 and a second columnar electrode 202 protruding on the first surface. The second surface of the semiconductor temperature control device 200 is mounted on an upper surface of the substrate 100. The semiconductor chip 300 includes opposed a back surface and a functional surface, with an external terminal 301 being on the functional surface. The back surface of the semiconductor chip 300 is mounted on the first surface of the semiconductor temperature control device 200. The molding layer 104 covers the semiconductor chip 300 and the semiconductor temperature control device 200 and disposed on the upper surface of the substrate 100. The molding layer 104 exposes the top surfaces of the first columnar electrode 201, the second columnar electrode 202, and the external terminal 301. The first external connection protrusion 106 is electrically connected to the first columnar electrode 201, the second external connection protrusion 107 electrically connected to the second columnar electrode 202, and the third external connection protrusion 108 electrically connected to the external terminal 301 disposed on the molding layer 104.

In some embodiments, referring to FIG. 2, the semiconductor temperature control device 200 includes a plurality of N-type semiconductors 204 and a plurality of P-type semiconductors 205 arranged in a staggered manner and connected in series. A top layer ceramic substrate 208 is disposed on the top surface of the plurality of N-type semiconductors 204 and P-type semiconductors 205, and a bottom layer ceramic substrate 209 is disposed on the bottom surface of the plurality of N-type semiconductors 204 and P-type semiconductors 205. The first columnar electrode 201 and the second columnar electrode 202 protrude on the surface of the top layer ceramic substrate 208, and are electrically connected to one N-type semiconductor 204 and P-type semiconductor 205 at both ends of the plurality of N-type semiconductors 204 and P-type semiconductors 205 connected in series.

In some embodiments, the back surface of the semiconductor chip 300 is mounted to the surface of the top layer ceramic substrate 208 of the semiconductor temperature control device 200 by a thermal conductive adhesive 302.

In some embodiments, the semiconductor chip 300 is mounted on the upper surface of the semiconductor temperature control device 200 between the first columnar electrode 201 and the second columnar electrode 202, or mounted on the upper surface of the semiconductor temperature control device 200 on one side of the first columnar electrode 201 and the second columnar electrode 202.

In some embodiments, the top surface of the external terminal 301 on the functional surface of the semiconductor chip 300 is flush with the top surfaces of the first columnar electrode 201 and the second columnar electrode 202 protruding from the first surface of the semiconductor temperature control device 200.

In some embodiments, the packaging structure further includes a first redistribution layer 101 electrically connected to the first columnar electrode 201, a second redistribution layer 102 electrically connected to the second columnar electrode 202, and a third redistribution layer 103 electrically connected to the external terminal 301 disposed on the molding layer 104. The first external connection protrusion 106 is disposed on the first redistribution layer 101 and electrically connected to the first redistribution layer 101, the second external connection protrusion 107 is disposed on the second redistribution layer 102 and electrically connected to the second redistribution layer 102, and the third external connection protrusion 108 is disposed on the third redistribution layer 103 and electrically connected to the third redistribution layer 103.

The foregoing description of the specific embodiments can be readily modified and/or adapted for various applications. Therefore, such adaptations and modifications are intended to be within the meaning and range of equivalents of the disclosed embodiments, based on the teaching and guidance presented herein. The breadth and scope of the present disclosure should not be limited by any of the above-described exemplary embodiments, but should be defined only in accordance with the following claims and their equivalents.

What is claimed is:

1. A method for forming a packaging structure, comprising:
providing a substrate;
providing a semiconductor temperature control device, the semiconductor temperature control device comprising opposed a first surface and a second surface, with a first columnar electrode and a second columnar electrode protruding on the first surface;
mounting the second surface of the semiconductor temperature control device on an upper surface of the substrate;
providing a semiconductor chip, the semiconductor chip comprising opposed a back surface and a functional surface, with an external terminal being on the functional surface;
mounting the back surface of the semiconductor chip on the first surface of the semiconductor temperature control device;
forming, on the upper surface of the substrate, a molding layer covering the semiconductor chip and the semiconductor temperature control device, the molding layer exposing top surfaces of the first columnar electrode, the second columnar electrode, and the external terminal; and
forming, on the molding layer, a first external connection protrusion electrically connected to the first columnar electrode, a second external connection protrusion electrically connected to the second columnar electrode, and a third external connection protrusion electrically connected to the external terminal.

2. The method according to claim 1, wherein the first external connection protrusion and the second external connection protrusion are configured to be electrically connected with positive and negative electrodes of a direct current (DC) power source, so that the semiconductor temperature control device operates to absorb heat generated by the semiconductor chip, and the semiconductor temperature control device forms a cold end and a hot end during operation, with the cold end being an end close to the first surface and the hot end being another end close to the second surface.

3. The method according to claim 1, wherein
the semiconductor temperature control device comprises:
a plurality of N-type semiconductors and a plurality of P-type semiconductors arranged in a staggered manner and connected in series;
a top layer ceramic substrate disposed on top surface of the plurality of N-type semiconductors and the plurality of P-type semiconductors; and
a bottom layer ceramic substrate disposed on bottom surface of the plurality of N-type semiconductors and the plurality of P-type semiconductors; and
the first columnar electrode and the second columnar electrode protrude on a surface of the top layer ceramic substrate, and are electrically connected to one N-type semiconductor and one P-type semiconductor at both ends of the plurality of N-type semiconductors and the plurality of P-type semiconductors connected in series.

4. The method according to claim 3, wherein the back surface of the semiconductor chip is mounted to the surface of the top layer ceramic substrate of the semiconductor temperature control device by a thermal conductive adhesive.

5. The method according to claim 1, wherein the semiconductor chip is mounted on the first surface of the semiconductor temperature control device between the first columnar electrode and the second columnar electrode, or mounted on the first surface of the semiconductor temperature control device on a side of the first columnar electrode and the second columnar electrode.

6. The method according to claim 1, wherein, after the back surface of the semiconductor chip is mounted on the first surface of the semiconductor temperature control device, a top surface of the external terminal on the functional surface of the semiconductor chip is flush with the top surfaces of the first columnar electrode and the second columnar electrode protruding on the first surface of the semiconductor temperature control device.

7. The method according to claim 1, further comprising:
forming, on the molding layer, a first redistribution layer electrically connected to the first columnar electrode, a second redistribution layer electrically connected to the second columnar electrode, and a third redistribution layer electrically connected to the external terminal,
wherein the first external connection protrusion is disposed on the first redistribution layer and electrically connected to the first redistribution layer, the second external connection protrusion is disposed on the second redistribution layer and electrically connected to the second redistribution layer, and the third external connection protrusion is disposed on the third redistribution layer and electrically connected to the third redistribution layer.

8. The method according to claim 1, wherein
the substrate comprises a plurality of packaging areas arranged in an array, and a sawing street area disposed between adjacent packaging areas;
the semiconductor temperature control device and semiconductor chip are mounted correspondingly on the upper surface of each packaging area;
the molding layer further covers the upper surface of the sawing street area of the substrate; and
after forming the first external connection protrusion, the second external connection protrusion, and the third external connection protrusion, the molding layer and the substrate are diced along the sawing street area to form a plurality of discrete packages.

9. A packaging structure, comprising:
a substrate;
a semiconductor temperature control device, the semiconductor temperature control device comprising opposed a first surface and a second surface, with a first columnar electrode and a second columnar electrode protruding on the first surface, the second surface of the semiconductor temperature control device being mounted on an upper surface of the substrate;
a semiconductor chip, the semiconductor chip comprising opposed a back surface and a functional surface, with an external terminal being on the functional surface, the back surface of the semiconductor chip being mounted on the first surface of the semiconductor temperature control device;
a molding layer covering the semiconductor chip and the semiconductor temperature control device and disposed on the upper surface of the substrate, the molding layer exposing top surfaces of the first columnar electrode, the second columnar electrode, and the external terminal; and
a first external connection protrusion disposed on the molding layer and electrically connected to the first columnar electrode, a second external connection protrusion disposed on the molding layer and electrically connected to the second columnar electrode, and a third external connection protrusion disposed on the molding layer and electrically connected to the external terminal.

10. The packaging structure according to claim 9, wherein the first external connection protrusion and the second external connection protrusion are configured to be electrically connected with positive and negative electrodes of a direct connect (DC) power source, so that the semiconductor temperature control device operates to absorb heat generated by the semiconductor chip, and the semiconductor temperature control device forms a cold end and a hot end during operation, with the cold end being an end close to the first surface and the hot end being another end close to the second surface.

11. The packaging structure according to claim 9, wherein
the semiconductor temperature control device comprises:
a plurality of N-type semiconductors and a plurality of P-type semiconductors arranged in a staggered manner and connected in series;
a top layer ceramic substrate disposed on top surface of the plurality of N-type semiconductors and the plurality of P-type semiconductors; and
a bottom layer ceramic substrate disposed on bottom surface of the plurality of N-type semiconductors and the plurality of P-type semiconductors; and
the first columnar electrode and the second columnar electrode protrude on a surface of the top layer ceramic substrate, and are electrically connected to one N-type semiconductor and one P-type semiconductor at both ends of the plurality of N-type semiconductors and the plurality of P-type semiconductors connected in series.

12. The packaging structure according to claim 11, wherein the back surface of the semiconductor chip is mounted to the surface of the top layer ceramic substrate of the semiconductor temperature control device by a thermal conductive adhesive.

13. The packaging structure according to claim 9, wherein the semiconductor chip is mounted on the first surface of the semiconductor temperature control device between the first columnar electrode and the second columnar electrode, or mounted on the first surface of the semiconductor temperature control device on a side of the first columnar electrode and the second columnar electrode.

14. The packaging structure according to claim 9, wherein a top surface of the external terminal on the functional surface of the semiconductor chip is flush with the top surfaces of the first columnar electrode and the second columnar electrode protruding on the first surface of the semiconductor temperature control device.

15. The packaging structure according to claim 9, further comprising:
a first redistribution layer on the molding layer and electrically connected to the first columnar electrode;
a second redistribution layer on the molding layer and electrically connected to the second columnar electrode; and
a third redistribution layer on the molding layer and electrically connected to the external terminal,
wherein the first external connection protrusion is disposed on the first redistribution layer and electrically connected to the first redistribution layer, the second external connection protrusion is disposed on the second redistribution layer and electrically connected to the second redistribution layer, and the third external connection protrusion is disposed on the third redistribution layer and electrically connected to the third redistribution layer.

16. The packaging structure according to claim 9, wherein the external terminal is a metal pillar protruding from the functional surface of the semiconductor chip or an external solder pad disposed on the functional surface of the semiconductor chip.

17. A packaging structure, comprising:
a semiconductor temperature control device comprising a first columnar electrode and a second columnar electrode protruding on a first surface of the semiconductor temperature control device;
a semiconductor chip comprising an external terminal on a first surface of the semiconductor chip that is opposite to a second surface of the semiconductor chip mounted on the first surface of the semiconductor temperature control device;
a molding layer covering the semiconductor chip and the semiconductor temperature control device and exposing the first columnar electrode, the second columnar electrode, and the external terminal; and
a first external connection protrusion disposed on the molding layer and electrically connected to the first columnar electrode, a second external connection protrusion disposed on the molding layer and electrically connected to the second columnar electrode, and a third external connection protrusion disposed on the molding layer and electrically connected to the external terminal.

18. The packaging structure according to claim 17, further comprising:
a substrate, wherein a second surface of the semiconductor temperature control device that is opposite to the first surface of the semiconductor temperature control device is mounted to the substrate.

19. The packaging structure according to claim 18, wherein the first external connection protrusion and the second external connection protrusion are configured to be electrically connected with positive and negative electrodes of a direct connect (DC) power source, so that the semiconductor temperature control device operates to absorb heat generated by the semiconductor chip, and the semiconductor temperature control device forms a cold end and a hot end during operation, with the cold end being an end close to the first surface and the hot end being another end close to the second surface.

20. The packaging structure according to claim 17, wherein the semiconductor chip comprises a high bandwidth memory (HBM).
